(19) United States
(12) Patent Application Publication
(10) Pub. No.: US 2006/0268511 A1
(43) Pub. Date: Nov. 30, 2006

(54) Circuit assembly and flat display having the same

(76) Inventor: Kwang Jin Jeong, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/442,130

(22) Filed: May 30, 2006

(30) Foreign Application Priority Data
May 31, 2005 (KR) 2005-0046333

(51) Int. Cl. H05K 7/20

(52) U.S. Cl. 361/690

(57) ABSTRACT

A circuit assembly includes a mount having a circuit element mounted thereon; a heat sink for absorbing and discharging heat generated from the circuit element around, the heat sink mounted on the circuit element on a surface opposite the mount and a noise isolator for isolating noise generated from the circuit board, the noise isolator mounted on the heat sink. The heat sink may include a base portion in surface contact with the circuit element and a top portion in surface contact with the noise isolator. A plurality of fins may be positioned between and parallel to the base and top portions. A plurality of fins may be positioned between and perpendicular to the base and top portions. The top portion may be co-extensive with the base portion, or may only extend past the base portion.

### BACKGROUND OF THE INVENTION

1. Field of the Invention

The present invention relates to a flat display. More particularly the present invention relates to a circuit assembly, and a flat display having the circuit assembly, which includes a heat sink and a noise isolator, which also dissipates heat, mounted on the heat sink, so as to improve heat dissipating efficiency and reduce noise.

2. Description of the Prior Art

Flat displays have been developed as substitutes for cathode ray tubes. Such flat displays include a liquid crystal display (LCD), an electro-luminescence display (ELD), a field emission display (FED) and a plasma display panel (PDP).

A PDP can display images using plasma discharge, and provides a complete digitalization and a large screen compared to that of other flat displays. The PDP may include front and back cases, a filter assembly, a panel, a heat conductive sheet, a frame, printed circuit boards (PCBs) and additional members which are contained between the front and back cases.

The PDP may have a plurality of electrodes for discharging electrons and discharge cells which may be defined by grids. The PDP may display an image using electrodes and a luminescent material. Display driving signals may be supplied to the electrodes from a display driving portion of the PCB which may be disposed on a back surface of the panel. The heat conductive sheet and the frame may be between the PCB and the panel.

The PCB may include a power supply portion for supplying power to operate the PDP and to generate display driving signals, an address driving portion for supplying different driving signals to each of the electrodes, a scan and sustain driving portion, and a buffer board for transmitting the signals from the power supply portion to the panel.

The driving portions may be provided on the PCB and the electrodes of the panel may be connected to one another, e.g., by cable members. For example, flexible printed circuits and tape carrier packages may be used as the cable members. Each of the tape carrier packages may be composed of a film type connecting member and a driving chip mounted on the connecting member. The flexible cable members may detour around the heat conductive sheet and the frame, and connect the driving portions formed on the PCB to the electrodes of the panel, respectively.

The PDP may display images by discharge in the panel, as described above. The PDP may be generally formed of two glass substrates, with electrodes and a dielectric substance between the two glass substrates. Discharge gases may fill the discharge cells formed in the space between the two substrates. The discharge gases may emit ultraviolet (UV) light through discharge. The UV light may collide with the luminescent material, e.g., phosphor, which, in turn, emits visible light.

In order to display images as described above, the PDP requires a very high voltage. Specifically, a large amount of energy is required for the excitation of the stable elements, i.e., the discharge gases, to the discharge UV light. The large amount of energy is supplied to the electrodes as display driving signals having high voltages.

The display driving signals having the high voltages may impose a burden on the display driving circuits formed on the PCB, as well as on the electrodes formed on the panel. Thus, the display driving signals may cause the electrodes and the display driving circuits to vibrate, and, thus, generate heat and noise. The vibration and the noise may have an adverse effect on the quality of the PDP. Further, heat is a main factor that damages elements driving the PDP.

Each of the driving portions may contain an intelligent power module (IPM) in which the driving signals are generated by power from the power supplying portion. The IPM controls the electricity having high electrical potential so as to generate and supply the driving signals. This makes the IPM generate a large amount of heat. This heat may cause the elements to malfunction and to be damaged.

FIG. 1 illustrates a cross-sectional view of a conventional display drive circuit board having a field effect transistor (FET). Referring to FIG. 1, the display driving circuit board 1 may include a PCB 10, a plurality of heat-sinks 50 which are coupled to the PCB 10, a plurality of FETs 20, which may be respectively attached to the heat-sinks 50 and electrically connected to the PCB 10, to drive a display. A noise isolator 70 may be coupled to an upper portion of each of the heat-sink 50 by coupling members 80 in order to isolate noise generated from the FETs 20. The heat-sinks 50 may absorb and discharge heat generated from the FETs 20. When the noise isolator 70 is made of a material having excellent heat conductivity, the noise isolator 70 may dissipate heat in addition to isolating noise.

FIG. 2 illustrates a cross-sectional view of a conventional display drive circuit board having an IPM 30 mounted on the PCB 10. Typically, a plurality of FETs is integrated to form the IPM 30. A heat-sink 60 for discharging heat of the IPM 30 may include fins extending perpendicularly to an upper surface of the IPM 30 to increase the rate of heat dissipation.

However, it is difficult to attach a noise isolator which reduces noise and improves heat dissipation to the heat sink 60.

### SUMMARY OF THE INVENTION

The present invention is therefore directed to a circuit assembly and a flat display including the same, which substantially overcome one or more of the disadvantages of the related art.

It is a feature of an embodiment of the present invention to provide a circuit assembly including a heat sink and a noise isolator, having a heat dissipating function, mounted on the heat sink, so as to improve heat dissipating efficiency and reduce noise.

It is another feature of an embodiment of the present invention to provide a flat display which has a display driving circuit assembly including a heat sink and a noise isolator having a heat dissipating function to be mounted on the heat sink, so as to improve heat dissipating efficiency and reduce noise.

It is another feature of an embodiment of the present invention to provide a heat sink including a base portion in surface contact with the circuit element to be cooled and a top portion in surface contact with the noise isolator.

At least one of the above and other features and advantages of the present invention may be realized by providing a circuit assembly, including a mount, a circuit element mounted on the mount, a heat sink for absorbing and dissipating heat generated from the circuit element, the heat sink being on the circuit element on a surface opposite a surface of the circuit element facing the mount, the heat sink including a base portion in surface contact with the circuit element and an extension portion having a plurality of fins which extend from the base portion, and a noise isolator for isolating noise, the noise isolator being on the heat sink.

The extension portion may include at least one bent fin having bent surface coupled to the noise isolator. The extension portion may include two bent fins positioned at both ends of the extension portion. The at least one bent fin is thicker than remaining fins.

A coupling member may be included for coupling the noise isolator and the at least one bent fin.

An angle between the base portion and each fin of the extension portion may be 90° and each bent surface may be at an angle of 90° to each fin. Each fin of the extension portion, other than fins having a bent surface, may have an end contacting with the noise isolator or may have an end spaced apart from the noise isolator.

At least one of the above and other features and advantages of the present invention may be realized by providing a circuit assembly including a mount, a circuit element mounted on the mount and electrically connected to the driving circuit, a heat sink for absorbing and dissipating heat generated from the circuit element, the heat sink being on the circuit element on a surface opposite a surface of the circuit element facing the mount, the heat sink including a base portion in surface contact with the mount and including a plurality of heat discharging fins arranged parallel with an upper portion of the circuit element and a fixture for fixing the heat discharging fins, and a noise isolator for isolating noise generated from the mount, the noise isolator being on the heat sink.

The heat sink may have a sectional shape similar to a Chinese character [symbol] . The heat sink may include an extension portion which has a plurality of fins extending perpendicular to the heat dissipating fins.

A thermally conductive pad, e.g., made from silicon material or thermal grease, may be between the heat sink and the noise isolator. The noise isolator may include an oblong plate. The noise isolator may be aluminum. The circuit element may be in surface contact with the mount.

Either driving circuit assembly may be used in a flat display including a frame and a panel attached to a front surface of the frame.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a cross-sectional view of a conventional display drive circuit assembly having a field effect transistor;

FIG. 2 illustrates a cross-sectional view of a conventional display drive circuit assembly having an intelligent power module;

FIG. 3 illustrates an exploded perspective view of a flat display having a display drive circuit assembly according to a first embodiment of the present invention, in which the display drive circuit assembly includes an intelligent power module;

FIG. 4 illustrates a cross-sectional view of the display drive circuit assembly of the display according to the first embodiment of the present invention, taken along a line A-A in FIG. 3;

FIG. 5 illustrates a cross-sectional view of a display drive circuit assembly having an intelligent power module according to a second embodiment of the present invention; and

FIG. 6 illustrates a cross-sectional view showing a display drive circuit assembly having an intelligent power module according to a third embodiment of the present invention.

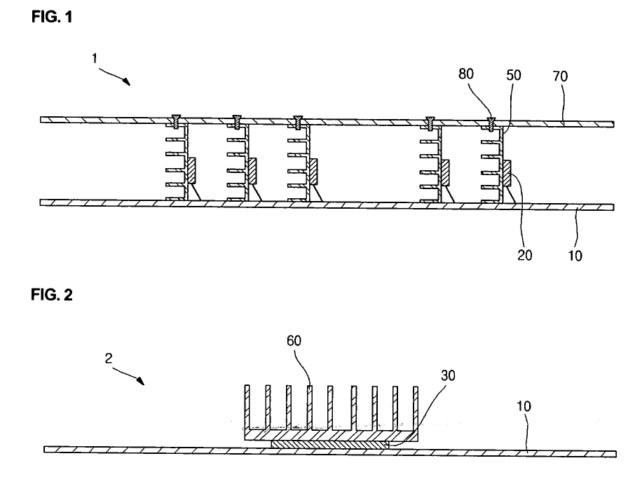

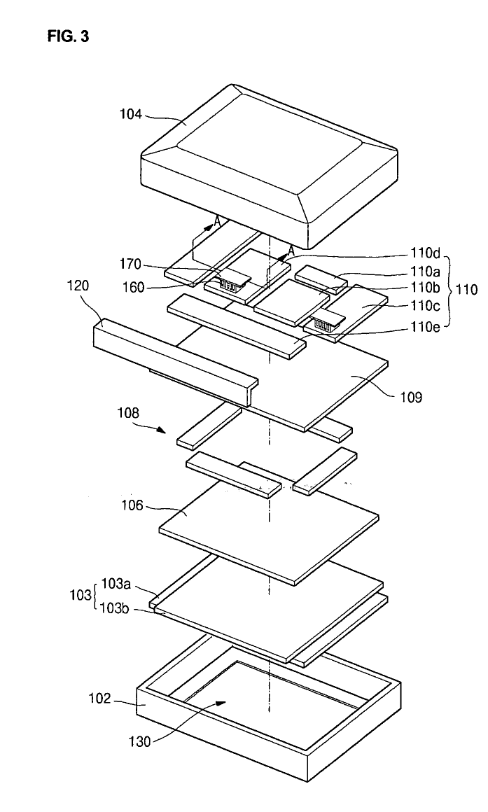

### DETAILED DESCRIPTION OF THE INVENTION

Korean Patent Application No. 2005-0046333, filed on May 31, 2005, in the Korean Intellectual Property Office, and entitled: Display Driving Circuit Board and Flat Type of Display Apparatus Having the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

FIG. 3 illustrates an exploded perspective view of a flat panel display having a display drive circuit assembly according to a first embodiment of the present invention.

Referring to FIG. 3, the display may include a front case 102, a back case 104, a panel 103, a heat conductive sheet 106, an adhesive member 108, a frame 109, a PCB assembly 110, a protective plate 120, a heat sink 160 and a noise isolator 170.

The front case 102 may be coupled to the back case 104 to protect the panel 103, the heat conductive sheet 106, the adhesive member 108, the frame 109, the PCB assembly 110, etc., therein from exterior contaminants and various impacts. Further, the front case 102 may prevent noise and vibration generated during an operation of the panel from being transmitted to a user. The frame 109 may have flanges (not shown), and the front case 102 may be coupled to the frame 109 through the flanges to more securely attach the heat conductive sheet 106, the adhesive member 108 and the panel 103 which are disposed between the front case 102 and the frame 109. Further, the front case 102 may have a light transmitting portion 130 in order to transmit light.

A filter assembly (not shown) may be disposed between the panel 103 and the light transmitting portion 130. The filter assembly may include a color compensation film for compensating colors by blocking certain wavelengths of visible light from the panel 103, an electromagnetic radiation isolating film for isolating electric electromagnetic radiation generated during operation of the display, and an anti-reflection film for preventing the quality of images from deteriorating due to internal and external reflections.

The back case 104 may be secured to the front case 102 to protect the structural members and elements from external contaminants and impact. Further, the back case 104 may have a dissipating opening formed therein to dissipate heat from inside the display. The back case 104 may be used as a ground for driving circuits on the PCB 110.

The panel 103 may be a PDP that displays images using discharge generated by driving signals provided from the driving portions on the PCB 110. In order to display the images, the panel 103 may include two or more substrates 103a and 103b and partitions, electrodes, a luminescent material, a dielectric material and a protective film, all of which may be disposed between the substrates. The panel 103 may have spaces in which discharges are generated, i.e., discharge cells. These discharge cells may be filled with discharge gases which, when discharge is generated, emit UV light with a wavelength band suitable for exciting the luminescent material.

This panel 103 may be connected to the driving portions of the PCB 110 by connecting members, e.g., flexible printed circuits and tape carrier packages. The tape carrier packages may be a film on which one or more driving chips may be mounted. Additional members, e.g., the adhesive member 108 and the heat conductive sheet 106, may be attached to a back surface of the panel 103.

The heat conductive sheet 106 may be inserted between the panel 103 and the frame 109 so as to transmit heat generated from the panel 103 towards the frame 109, thereby preventing the temperature of the panel 103 from unduly increasing. Further, the heat conductive sheet 106 may enable the temperature of the panel 103 to be uniformly distributed, so that damage or malfunction due to a local temperature difference of the panel 103 may be reduced or prevented.

The heat conductive sheet 106 may be attached to the frame 109 in another adhering manner, as appropriate for the material of the frame 109 or to change the use of the heat conductive sheet 106. For example, when the frame 109 is made of material having high heat conductivity and high heat dissipating ability, e.g., metal, the heat conductive sheet 106 can be in close contact to the frame 109. A significant amount of heat generated from the panel 103 may be transmitted through the heat conductive sheet 106 toward the frame 109 and dissipated, while some of heat of the panel 103 may be dissipated through the heat conductive sheet 106. On the other hand, when the frame 109 is made of material having low heat conductivity and low heat dissipating ability, e.g., synthetic resin, the heat conductive sheet 106 and the frame 109 may be disposed with a predetermined distance between them. At this time, most of the heat generated from the panel 103 may be dissipated by the heat conductive sheet 106, so that the panel 103 can be maintained at a substantially constant temperature.

The adhesive member 108 may secure the heat conductive sheet 106 or the panel 103 to the frame 109. The adhesive member 108 may include multiple strips that are adhered to edges of the heat conductive sheet 106 to form a frame shape, so as to fix the heat conductive sheet 106 or panel 103. The adhesive member 108 may be an adhesive agent, adhesive sheets and/or an adhesive tape. The adhesive member 108 may have various thicknesses and shapes, and may be adhered in different ways according to character of the frame 109.

As described above, when the frame 109 having low heat conductivity and low heat dissipating ability is used, the adhesive members 108 may be spaced at a predetermined distance from one another. The predetermined regular intervals between the adhesive members 108 may allow air to pass through the spaces between the adhesive members 108 to help the heat dissipation of the heat conductive sheet 106.

When the panel 103 is directly adhered to the frame 109 by the adhesive members 108, the adhesive members 108 may have a larger thickness to provide a gap between the heat conductive sheet 106 and the frame 109. Accordingly, air may flow through the gap may help the heat dissipation of the heat conductive sheet 106.

On the other hand, when the frame 109 having high heat conductivity and high heat dissipating ability is used, the adhesive member 108 may have a suitable shape and character to allow the heat conductive sheet 105 to be in close contact with the frame 109.

The panel 103 or the heat conductive sheet 106 may be attached to the frame 109 by the adhesive members 108. Further, the frame 109 may dissipate heat from the panel 103, the PCB assembly 110 and the tape carrier package according to its material characteristics. The frame 109 may have the PCB assembly 110 fixedly supported thereto by a coupling member, e.g., a boss or a screw. The material characteristics of the frame 109 determine whether the frame 109 is to come into close contact with the heat conductive sheet 106. In addition, when the frame 109 is made from an electrically conductive material, the frame 109 can be used to ground some of the driving circuits formed on the PCB assembly 110. Further, the frame 109 may have flanges (not shown) at edges or corners thereof. The frame 109 may be coupled to the front case 102 or the back case 104 through the flanges.

The PCB assembly 110 may have a circuit portion for driving the panel 103. The circuit portion may include a power supply portion for supplying power to the drive portions, an address drive portion, a scan drive portion and a sustain drive portion for applying driving signals to the electrodes of the panel 103. The PCB assembly 110 may include to multiple circuit boards, each having a driving portion. That is, the PCB assembly 110 may include a power supplying circuit board 110a having the power supplying portion formed thereon, an address driving circuit board 110c having the address driving portion formed thereon, a scan driving circuit board 110d having the scan driving portion formed thereon, a sustain driving circuit board having the sustain driving portion formed thereon (here, integrated with the scan driving circuit board 110d), a logic circuit board 110b for providing control signals to each driving circuit board and receiving signals from exterior devices and auxiliary circuit boards 110e having circuits for providing additional functions to the panel 103, respectively.

A driving buffer board 110e may be installed between the panel 103 and the driving circuit boards. The driving signals from each driving portion may be delivered to the panel 103 via the driving buffer board. The scan driving portion and the sustain driving portion may be integrated onto the scan driving circuit board 110d. Thus, the scan and sustain driving portions may have a common buffer board. Further, the driving buffer boards may be connected to the panel 103 by a connecting member, e.g., the tape carrier package or the flexible printed circuit. IPMs may be mounted on the circuit boards 110c and 110d having the address driving portion and the scan and sustain driving portion, respectively, in order to convert power from the power supplying portion into the driving signals according to the control signals from the logic control board 110b.

The protective plate 120 may protect the tape carrier package from outer impact along with the front and back cases 102 and 104, and may prevent damage and malfunction of the tape carrier package by absorbing and dissipating heat from the tape carrier package (not shown) to the heat sink. Thus, the protective plate 120 may have one surface coming into close contact with the driving chip of the tape carrier package and the other surface attached to the heat sink 160.

The heat sink 160 may dissipate heat from essential devices, e.g., the driving chip of the tape carrier package and the IPM, to reduce or prevent damage and/or malfunction of the essential devices. The noise isolator 170 may be coupled to upper portions of the heat sinks 160 by, e.g., coupling members, to isolate noise generated from the IPM. When this noise isolator 170 is made of a material having high heat conductivity, the noise isolator 170 may both isolate noise and dissipate heat.

Hereinafter, the circuit assembly including the heat sink and the noise isolator will be described in detail. ci

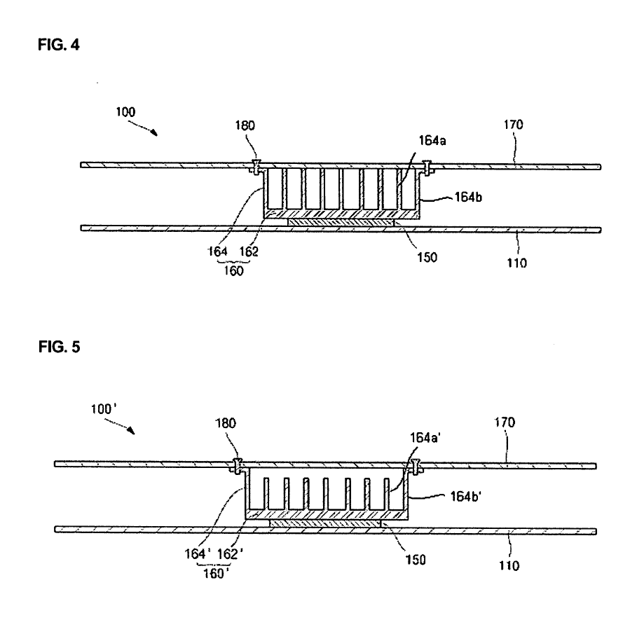

FIG. 4 illustrates a cross-sectional view of the circuit assembly of the display according to the first embodiment of the present invention, taken along a line A-A in FIG. 3.

Referring to FIG. 4, a circuit assembly 100 may include the PCB assembly 110, a circuit element 150 mounted on the PCB assembly 110 and electrically connected to the PCB assembly 110, the heat sink 160 mounted on the circuit element 150 to absorb and dissipate heat from the circuit element 150, and the noise isolator 170 mounted on the heat sink 160 to isolate noise from the circuit element 150. As shown in FIG. 4, the heat sink may be in surface contact with a major surface of the circuit element 150 and this surface contact may be with a surface of the circuit element 150 opposite the PCB assembly 110.

The heat sink 160 may have a base portion 162 in surface contact with the circuit element 150 and an extension portion 164 having plurality of fins 164a and at least one bent fin 164b extending from the base portion 162. In FIG. 4, each fin 164a and bent fin 164b of the extension portion 164 may be formed at an angle of 90° with respect to the base portion 162. The base portion 162 may dissipate some of the heat transferred through a surface of the circuit element 150 and may transfer most of the heat to the extension 164.

A bent portion of the bent fin 164b may couple the heat sink 160 to the noise isolator 170 to the heat sink 160. Assembly of the bent fin 164b and the noise isolator 170 may be achieved by coupling members 180, e.g., screws. Alternatively or additionally, the bent fin 164b may be attached to the noise isolator 170 by an adhesive layer. The adhesive layer may be a mechanically strong and thermally conductive material.

In FIG. 4, both end fins of the extension portion 164 may be bent fins 164b bent at an angle of 90° relative to the remainder of the extension portion 164. All fins 164a of the extension portion 164 may be in contact with the noise isolator 170 at an end thereof, as opposed to the surface contact of the bent fin 164b. The bent fin 164b may have a larger thickness than that of the remaining fins 164a, to further improve the transfer of the heat to the noise isolator 170. Further, a length of the bent portion of the bent fin 164b may be increased to improve transfer of heat to the noise isolator 170.

A pad or thermal grease, e.g., made from silicone, may be disposed between the heat sink 160 and the noise isolator 170. This allows the heat sink 160 to come in close thermal contact with the noise isolator 170, so that the heat may be effectively transferred from the heat sink 160 to the noise isolator 170. The noise isolator 170 may be an oblong plate made from a material having excellent heat conductivity, e.g., aluminum.

Therefore, the heat generated from the circuit element, e.g., from the IPM, may be transferred through the base portion 162 and each fin 164a to the noise isolator 170, which is in contact with end of each fin, and through a surface of each bent fin 164b to the noise isolator 170, and finally dissipated. Of course, the heat generated from the IPM may also be dissipated by the IPM and the heat sink 160.

FIG. 5 illustrates a cross-sectional view of a display driving circuit board having an IPM according to a second embodiment of the present invention.

Referring to FIG. 5, the circuit assembly 100′ may include a heat sink 160′ having an extension portion 164′ having a plurality of fins 164a′ and bent fins 164b′. The fins 164a′ may be spaced apart from the noise isolator 170 and arranged between the both bent fins 164b′. This arrangement may allow the heat sink 160′ to obtain a chimney effect, since both bent fins 164b′ are longer than the remaining fins 164a′, increasing a cooling efficiency for the circuit element.

The circuit assembly 100′ shown in FIG. 5 may have the same elements and members as those of the circuit assembly 100 of FIG. 4, except for the heat sink 160′. Therefore, the description of the structural elements and members of the circuit assembly 100′ will be omitted.

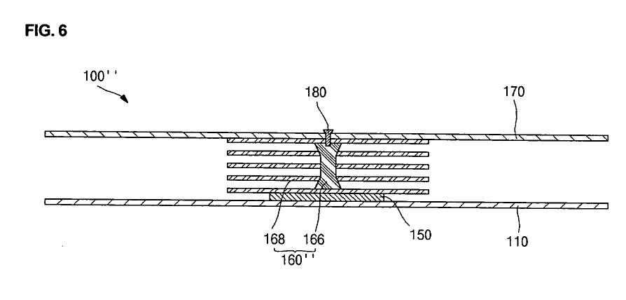

FIG. 6 illustrates a cross-sectional view of a circuit assembly 100′ having an IPM according to a third embodiment of the present invention. Referring to FIG. 6, a heat sink 160″ of the circuit assembly 100″ may include a plurality of heat dissipating fins 168 in parallel with an upper surface of the circuit board 150 and a fixture 166 for fixing the fins 168 parallel with one another.

The fixture 166 may be positioned at a center portion of the heat dissipating fins 168 to be perpendicular to the fins 168. Therefore, the heat sink 160″ may have a sectional shape similar to the Chinese character [symbol] . Since a top fin of the heat sink 160″ is parallel with the upper surface of the circuit element 150, the noise isolator 170 can be easily coupled to the heat sink 160″. In FIG. 6, the noise isolator 170 may be coupled to the fixture 166 of the heat sink 160″ by a coupling member 180, e.g., a screw, or by any appropriate securing mechanism.

The heat sink 160″ may include an extension (not shown) which has pins extending in a direction perpendicular to the heat dissipating fins 16, e.g., as shown in FIG. 4 or 5, or in the plane of the page. Furthermore, two or more heat sinks 160″ having the sectional shape of the Chinese character [symbol] may be mounted on the printed circuit board in series.

While the present invention is described in relation to a PDP, it will be understood that the present invention can be applied to other types of flat displays. Although the present invention is described with relation to the display driving circuit board, i.e., a PCB, the present invention can be applied to the a carrier package having a driving chip mounted thereon. When using a tape carrier package, the driving chip may be installed in a film type of connecting member, instead of on the circuit board and the PCB corresponding to the driving chip and the connecting member respectively.

In accordance with the present invention, a heat sink may include a base portion in surface contact with the circuit element and a top portion in surface contact with the noise isolator. A plurality of fins may be positioned between and parallel to the base and top portions. A plurality of fins may be positioned between and perpendicular to the base and top portions. The top portion may be co-extensive with the base portion, or may only extend past the base portion.

In the display driving circuit board and the flat display having the same, according to the present invention, the structure of the heat sink may be improved by coupling the noise isolator having the heat dissipating function to the heat sink, thereby efficiently dissipating the heat generated from the operating circuit element. Thus, it is possible to prevent damage and malfunction of the elements, to secure a stable operation of the display apparatus, and to reduce the noise.

Exemplary embodiments of the present invention have been disclosed herein, and although specific terms are employed, they are used and are to be interpreted in a generic and descriptive sense only and not for purpose of limitation. For example, while air has been referred to as aiding in the cooling, any other suitable cooling fluid maybe used. Further, while the bent fins are shown as being located at end of the extension portion, they may be located elsewhere in the extension portion. Accordingly, it will be understood by those of ordinary skill in the art that various changes in form and details may be made without departing from the spirit and scope of the present invention as set forth in the following claims.

What is claimed is:

1. A circuit assembly, comprising:
a mount;
a circuit element mounted on the mount;
a heat sink for absorbing and dissipating heat generated from the circuit element, the heat sink being on the circuit element on a surface opposite a surface of the circuit element facing the mount, the heat sink including a base portion in surface contact with the circuit element and an extension portion having a plurality of fins which extend from the base portion; and
a noise isolator for isolating noise, the noise isolator being on the heat sink.

2. The circuit assembly as claimed in claim 1, wherein the extension portion includes at least one bent fin having bent surface coupled to the noise isolator.

3. The circuit assembly as claimed in claim 2, wherein the extension portion includes two bent fins positioned at both ends of the extension portion.

4. The circuit assembly as claimed in claim 2, further comprising a coupling member for coupling the noise isolator and the at least one bent fin.

5. The circuit assembly as claimed in claim 2, wherein an angle between the base portion and each fin of the extension portion is 90° and each bent surface is at an angle of 90° to each fin.

6. The circuit assembly as claimed in claim 2, wherein each fin of the extension portion, other than fins having a bent surface, has an end contacting with the noise isolator.

7. The circuit assembly as claimed in claim 2, wherein each fin of the extension portion, other than fins having a bent surface, has an end spaced apart from the noise isolator.

8. The circuit assembly as claimed in claim 2, wherein the at least one bent fin is thicker than other fins.

9. The circuit assembly as claimed in claim 1, further comprising a thermally conductive pad between the heat sink and the noise isolator.

10. The circuit assembly as claimed in claim 1, wherein the noise isolator includes an oblong plate.

11. The circuit assembly as claimed in claim 1, wherein the noise isolator is aluminum.

12. A circuit assembly, comprising:
a mount;
a circuit element mounted on the mount and electrically connected to the driving circuit;
a heat sink for absorbing and dissipating heat generated from the circuit element, the heat sink being on the circuit element on a surface opposite a surface of the circuit element facing the mount, the heat sink including a base portion in surface contact with the mount and including a plurality of heat discharging fins arranged parallel with an upper portion of the circuit element and a fixture for fixing the heat discharging fins; and
a noise isolator for isolating noise, the noise isolator being on the heat sink.

13. The circuit assembly as claimed in claim 12, wherein the heat sink has a sectional shape similar to a Chinese character [symbol] .

14. The circuit assembly as claimed in claim 13, wherein the heat sink further includes an extension portion which has a plurality of auxiliary fins extending perpendicular to the heat dissipating fins.

15. A flat display, comprising:
a frame;
a panel attached to a front surface of the frame; and
a circuit assembly, including
a mount,
a circuit element mounted on the mount,
a heat sink for absorbing and dissipating heat generated from the circuit element, the heat sink being on the circuit element on a surface opposite a surface of the circuit element facing the mount, the heat sink including a base portion in surface contact with the circuit element and an extension portion having a plurality of fins which extend from the base portion, and
a noise isolator for isolating noise, the noise isolator being on the heat sink.

16. The flat display as claimed in claim 15, wherein some of the fins of the extension portion are bent to form a bent surface so that the bent fins are coupled to the noise isolating means.

17. A flat display, comprising:
a frame;
a panel attached to a front surface of the frame; and
a driving circuit assembly including
a mount,
a circuit element mounted on the mount and electrically connected to the driving circuit,
a heat sink for absorbing and dissipating heat generated from the circuit element, the heat sink being on the circuit element on a surface opposite a surface of the circuit element facing the mount, the heat sink including a base portion in surface contact with the mount and including a plurality of heat discharging fins arranged parallel with an upper portion of the circuit element and a fixture for fixing the heat discharging fins, and
a noise isolator for isolating noise, the noise isolator being on the heat sink.
